(19) United States
(12) Patent Application Publication
(10) Pub. No.: US 2025/0346124 A1
(43) Pub. Date: Nov. 13, 2025

(54) ZONAL ARCHITECTURE CIRCUIT DESIGN

(71) Applicant: Rivian IP Holdings, LLC, Irvine, CA (US)

(72) Inventors: Steven HANG, Long Beach, CA (US); Long Phi HUYNH, Brea, CA (US); Glenn Morris FEINBERG, Carlsbad, CA (US)

(21) Appl. No.: 19/200,531

(22) Filed: May 6, 2025

Related U.S. Application Data
(60) Provisional application No. 63/643,433, filed on May 7, 2024.
(60) Provisional application No. 63/656,585, filed on Jun. 5, 2024.

(51) Int. Cl. B60L 3/00; B60L 1/14; B60L 50/60; B60R 16/033

(52) U.S. Cl. CPC B60L 3/0092; B60L 1/14; B60L 3/0084; B60L 50/66; B60R 16/033; B60L 2210/12

(57) ABSTRACT

A vehicle with a zonal architecture for power distribution may include east and west electronic control units (ECUs) operating components on respective sides of the vehicle's longitudinal axis, and a south ECU at the rear. The east ECU features a low voltage direct current to direct current (DCDC) support circuit block. ECU functions may be distributed based on geographic zones, allowing for backup operations if a primary unit fails.

### CROSS REFERENCE TO RELATED APPLICATION(S)

The present application claims the benefit of U.S. Provisional Application No. 63/643,433, entitled “ZONAL ARCHITECTURE CIRCUIT DESIGN”, filed on May 7, 2024, and U.S. Provisional Application No. 63/656,585, entitled “ZONAL ARCHITECTURE CIRCUIT DESIGN”, filed on Jun. 5, 2024, all of which are incorporated herein for reference in their entirety.

### INTRODUCTION

This application is directed to zonal architecture for functional and power distribution and circuit designs thereof, and more particularly, associated with an electric vehicle.

### SUMMARY

The disclosed subject matter provides for zonal architecture for power distribution and circuit designs thereof that allows for redundancy in power distribution.

### BRIEF DESCRIPTION OF THE DRAWINGS

Certain features of the subject technology are set forth in the appended claims. However, for purpose of explanation, several embodiments of the subject technology are set forth in the following figures.

FIG. 1A illustrates an example overhead view of a vehicle with zonal power distribution as described herein.

FIG. 1B illustrates an example side view of a vehicle with zonal power distribution as described herein.

FIG. 1C illustrates an example block diagram of a system with zonal power distribution as described herein.

FIG. 2 illustrates an example schematic block diagram of the circuit blocks.

FIG. 3 illustrates an example schematic block diagram of the circuit blocks.

FIG. 4 illustrates an example schematic block diagram of the circuit blocks.

### DETAILED DESCRIPTION

The detailed description set forth below is intended as a description of various configurations of the subject technology and is not intended to represent the only configurations in which the subject technology may be practiced. The appended drawings are incorporated herein and constitute a part of the detailed description. The detailed description includes specific details for the purpose of providing a thorough understanding of the subject technology. However, it will be clear and apparent to those skilled in the art that the subject technology is not limited to the specific details set forth herein and may be practiced without these specific details. In some instances, well-known structures and components are shown in block diagram form in order to avoid obscuring the concepts of the subject technology.

The disclosed subject matter provides for a zonal architecture for power distribution and circuit design thereof that allows for redundancy in power distribution and therefore may protect against the loss of one or more power buses or electronic control units (ECUs). The ECU functions of the zonal architecture may be based on geographic zone of a vehicle, such as front left, front right, or rear zone. In addition, there may be two or more power sources for low voltage power distribution. In an example, each ECU may be provided continuous power from direct current to direct current converter (DCDC) wherein the DCDC steps down from a high voltage battery pack and may provide power from a low voltage (LV) battery (e.g., 12V battery). As further described herein, if there is a fault on a first power source (e.g., DCDC bus), then a second power source (e.g., LV battery bus) may power the vehicle to operate one or more functions, which may be functions associated with critical tasks. For example, the advanced driver assistance system (ADAS) system of the vehicle may continue to be powered to keep the vehicle moving appropriately until a user takes over. In addition, there may be redundant functions for each ECU, therefore, if a first ECU fails, a second ECU may continue to operate the redundant functions or other ECU specific functions.

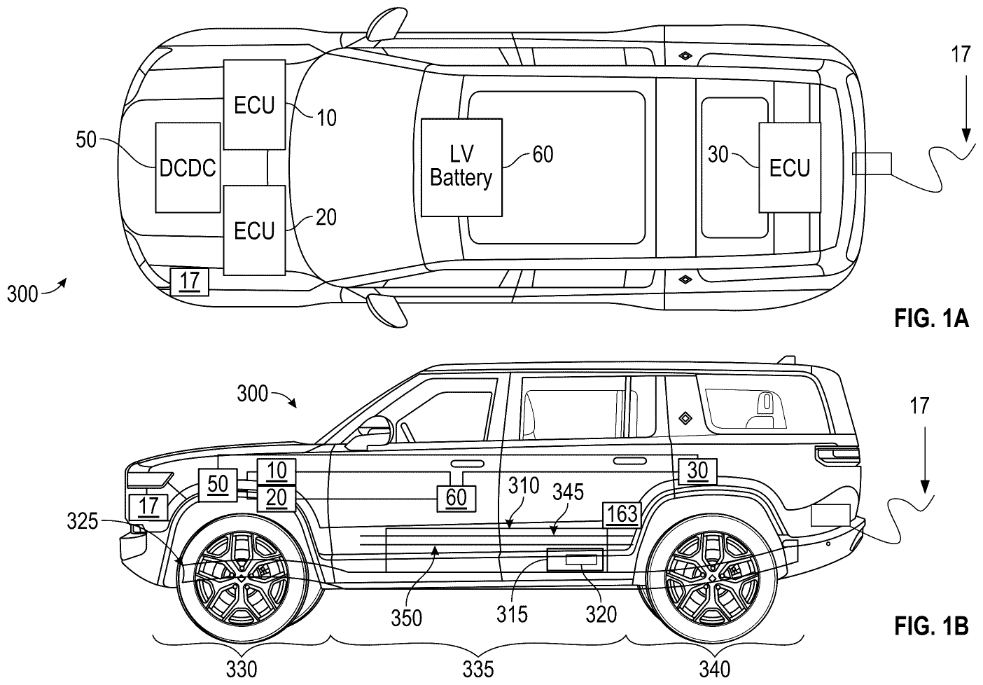

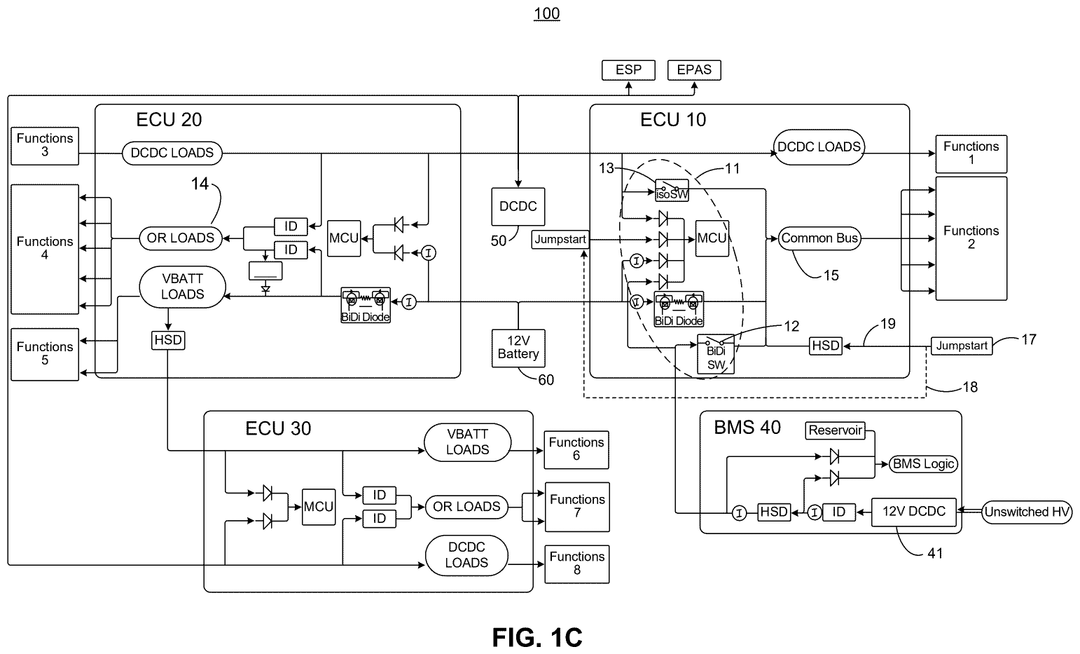

FIG. 1A illustrates an example overhead view of vehicle 300. As further described herein, vehicle 300 may include electronic control units (ECUs) in front portion 330 of vehicle 300 (e.g., ECU 10 and ECU 20), an ECU in rear portion 340 of vehicle 300 (e.g., ECU 30), direct current to direct current converter (DCDC) 50, low voltage (LV) battery 60 (e.g., 12V battery), or jumpstart access 17, among other things.

FIG. 1B illustrates an example side view of vehicle 300. As shown, the vehicle 300 may include one or more battery packs, such as high voltage (HV) battery pack 310 (e.g., 450V), which may be located near the center body portion 335 of vehicle 300. HV battery pack 310 may be coupled with one or more electrical systems of the vehicle 300 to provide power to the electrical systems. As further described herein, ECU 10, ECU 20, or ECU 30 may be communicatively connected with or have power distributed with each other and may be functionally redundant for power or other operations of electronic components of vehicle 300.

In one or more implementations, the vehicle 300 may be an electric vehicle having one or more electric motors that drive the wheels 302 of the vehicle using electric power from HV battery pack 310. In one or more implementations, the vehicle 300 may also, or alternatively, include one or more chemically-powered engines, such as a gas-powered engine or a fuel cell powered motor. For example, electric vehicles can be fully electric or partially electric (e.g., hybrid or plug-in hybrid). In various implementations, the vehicle 300 may be a fully autonomous vehicle that can navigate roadways without a human operator or driver, a partially autonomous vehicle that can navigate some roadways without a human operator or driver or that can navigate roadways with the supervision of a human operator, may be an unmanned vehicle that can navigate roadways or other pathways without any human occupants, or may be a human operated (non-autonomous) vehicle configured for a human operator.

In the example of FIG. 1B, the vehicle 300 may be implemented as a truck (e.g., a pickup truck) having a battery pack 310. As shown, HV battery pack 310 may include on or more battery modules 315, which may include one or more battery cells 320. However, this is merely illustrative and, in other implementations, HV battery pack 310 may be provided without any battery modules 315 (e.g., in a cell-to-pack configuration).

As shown in FIG. 1B, the vehicle 300 may include a support structure such as a chassis 325 (e.g., a frame, internal frame, or other support structure). The chassis 325 may support various components of the vehicle 300. As shown, the chassis 325 may span a front portion 330 (e.g., a hood or bonnet portion), center body portion 335, and a rear portion 340 (e.g., a trunk, payload, or boot portion) of the vehicle 300 in some implementations. In one or more implementations, HV battery pack 310 may be installed on the chassis 325 (e.g., within one or more of the front portions 330, center body portion 335, or the rear portion 340). As shown, HV battery pack 310 may include or be electrically coupled with one or more one busbars (e.g., one or more current collector elements). In the example of FIG. 1B, the vehicle 300 includes a first busbar 345 and a second busbar 350, either or both of which may include electrically conductive material to connect or otherwise electrically couple the battery module(s) 315 or the battery cell(s) s 320 with other electrical components of the vehicle 300 to provide electrical power to various systems or components of the vehicle 300.

In other implementations, the vehicle 300 may be implemented as another type of electric truck, an electric delivery van, an electric automobile, an electric car, an electric motorcycle, an electric scooter, an electric passenger vehicle, an electric passenger or commercial truck, a hybrid vehicle, or other vehicles such as sea or air transport vehicles, planes, helicopters, submarines, boats, or drones, and/or any other movable apparatus having a battery pack 310 (e.g., that powers the propulsion or drive components of the moveable apparatus).

FIG. 1C illustrates an example block diagram of system 100 that may include a plurality of ECUs of vehicle 300. An ECU is an embedded system that may control one or more of the electrical systems or subsystems in a vehicle. The positioning and connections of ECU 10, ECU 20, or ECU 30 may provide for a level of redundancy for faults, which may be caused by collisions or other malfunctions. The design of system 100 may allow vehicle 300 to safely operate for a period after the fault, such as being able to drive vehicle 300 (e.g., steer, brake, or accelerate) to a safe position off of a roadway or being able to operate electronic controlled functions (e.g., door latches) of vehicle 300, among other things. As shown, ECU 10, ECU 20, and ECU 30 may be connected with DCDC 50 (also referred herein as DCDC bus 50) to operate DCDC loads and a low voltage (LV) battery 60 (e.g., 12V battery or LV battery bus 60) to operate LV battery loads. In an example, one or more ECUs (e.g., ECU 10) may include a fault isolation system 11. Fault isolation system 11 may include isolation switch or a bidirectional (Bidi) switch 12. In some configurations, in consideration of safety, only one ECU (e.g., ECU 10) may include fault isolation system 11. As shown, ECU 10 may include a common bus 15, which may operate slightly differently than other buses (e.g., OR load bus 14), as the common bus may allow for bidirectional power to be transmitted to and from LV battery 60 that may be a function of using fault isolation system 11. The common bus (specific to ECU 10) allows power to flow bidirectionally, from LV battery 60 to DCDC 50, or from DCDC 50 to LV battery 60. The OR bus does not allow power to flow bidirectionally (it does not connect or isolate LV battery 60 and DCDC 50 networks). The other element, which is a shared attribute of both common bus and OR Bus, that in the event of a failure of the DCDC 50 or LV battery 60, the common bus (or OR Bus) will retain operation (e.g., will be available).

With continued reference to FIG. 1C, each ECU may have on or more dedicated functions that may be powered by DCDC 50, LV battery 60, or LV DCDC 41. ECU 10 may operate functions 1, functions 2, and jumpstart functions. ECU 10 may be connected with jumpstart access 17 (e.g., wiring located in a rear portion 340 of vehicle 300). Jumpstart access 17 may allow an external power source (e.g., jumpstart pack) to connect with ECU 10 in order to jumpstart electronic functions of the vehicle, particularly when LV battery 60 is depleted. As further described herein, jumpstart access 17 may have multiple routes that include jumpstart route 18 (e.g., to microcontroller) and jumpstart route 19 (e.g., to Bidi switch 12). Functions 1 may include functions such as first row universal serial bus, or electronic stability program (ESP), among other things. Functions 2 may include functions such as right door latch, passenger seat motor, right headlamp, alarm module, or frunk latch, among other things. In this example, functions 1 of ECU 10 may only be powered by DCDC 50, while functions 2 of ECU 10 may be powered by DCDC 50 (which may be the primary power) or LV battery 60 (which may be the secondary power), which may be referred to common bus 15. ECU 10 may be located on the right front of vehicle 300 and therefore may operate functions primarily (e.g., most or all) for the right portion of vehicle 300.

As shown in FIG. 1C, ECU 20 may operate functions 3, functions 4, and functions 5. Functions 3 may include functions such as front suspension valves, or autonomy control module, among other things. Functions 4 may include functions such as steering angle sensor, front wiper motor, left door latches, left headlamp, exterior near field communication (NFC), or on-board diagnostics (OBD) port, among other things. Functions 5 may include functions such as electric power assisted steering (EPAS), charge port door, interior NFC, or electric powered assisted breaking, among other things. In this example, functions 3 of ECU 20 may only be powered by DCDC 50 and functions 5 of ECU 20 may only be powered by LV battery 60. Functions 4 of ECU 20 may be powered by DCDC 50 (which may be the primary power) or LV battery 60 (which may be the secondary power), which may be referred to OR loads 14 (also referred herein as OR load bus 14). ECU 20 may be located on the left front of vehicle 300 and therefore may operate functions primarily (e.g., most or all) for the left portion of vehicle 300.

As shown in FIG. 1C, ECU 30 may operate functions 6, functions 7, and functions 8. Functions 6 may include functions such as license plate lamp. Functions 7 may include functions such as rear vehicle access system sensors, liftgate latch, trailer brake, right lamp rear, or left lamp rear, among other things. Functions 8 may include functions such as right trailer brake lamp, or rear suspension valves, among other things. In this example, functions 8 of ECU 30 may only be powered by DCDC 50 and functions 6 of ECU 30 may only be powered by LV battery 60. Functions 7 of ECU 30 may be powered by DCDC 50 (which may be the primary power) or LV battery 60 (which may be the secondary power). ECU 30 may be located on the rear of vehicle 300 and therefore may operate functions primarily (e.g., most or all) for the rear portion of vehicle 300.

System 100 of FIG. 1C may include a battery management system (BMS) 40. BMS 40 may be located at or near HV battery pack 310 of FIG. 1B, which LV DCDC 41 converts the HV DC to a lower voltage, such as 14V. LV DCDC 41 may help reduce the need for LV battery 60 for some operations, such as when vehicle 300 is in standby mode (e.g., parked). It is contemplated that the functions disclosed herein (e.g., functions 1 through functions 8) may be controlled by other ECUs or powered by any of the listed power sources.

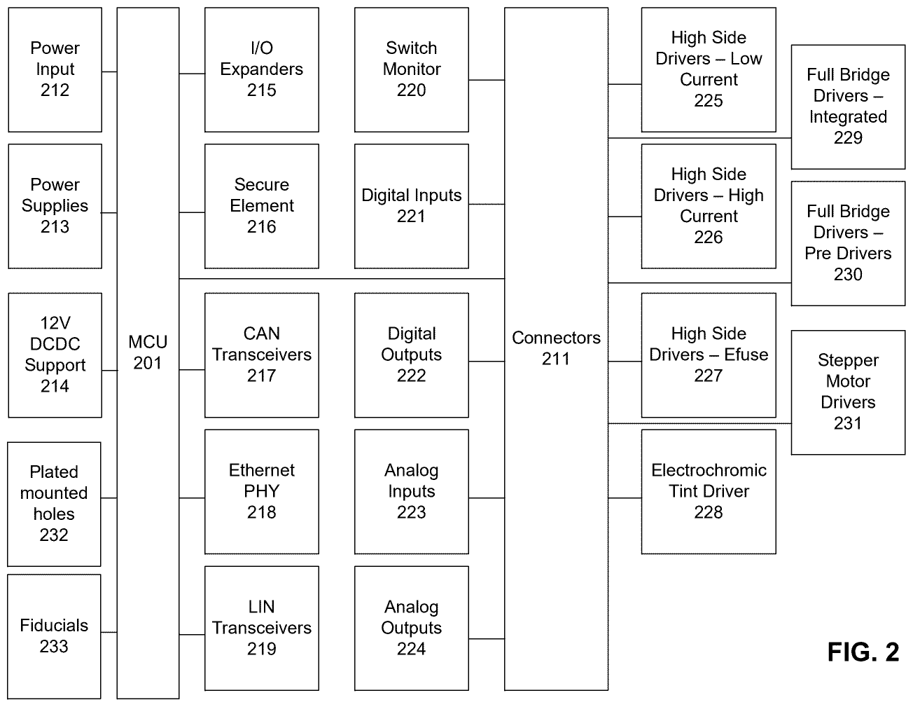

FIG. 2 illustrates an example schematic block diagram of the circuit blocks of ECU 10 of FIG. 1C. ECU 10 may be located on the east (e.g., right) side of vehicle 300. ECU 10 may include functions, such as front headlamps control, front seat control, front door control (e.g., windows, door switch, lock, mirrors), power distribution (e.g., power to accessory power ports, switch packs, or buttons), vehicle temperature signals, controls thermal components, controls frunk, connects redundant power sources together, maintains high safety integrity of vehicle power sources, or monitor/control 12V battery state of health and state of charge, among other things. These functions may be executed in part by one or more circuit blocks as disclosed herein.

As shown, there may be several functions unique to ECU 10 and therefore unique circuit blocks to each ECU. In an example, ECU 10 may include an electrochromic tint driver block 228 (e.g., an electrical circuit to drive the tint on mirrors), low voltage (e.g., 10-14V) DCDC support block 214, plated mounted holes block 232, fiducials block 233, or secure element block 216, among others which may not be present in other zones. ECU 10 may include connectors block 211 (e.g., block to ground or other blocks), power input block 212, power supplies block 213, MCU block 201, I/O expanders block 215, CAN transceivers block 217, Ethernet PHY block 218 (e.g., communications with Ethernet), LIN transceivers block 219, switch monitor block 220 (e.g., multi-switch detection interface (MSDI)), digital inputs block 221, digital outputs block 222, analog inputs block 223, analog outputs block 224, high side drivers (HSD)—low current block 225, high side drivers—high current block 226, high side drivers—efuse block 227, full bridge drivers—integrated bock 229, full bridge drivers—pre-drivers block 230, or stepper motor drivers block 231. Each block may have a plurality of pins to enable functionality as disclosed herein. Each block may interconnect one or more other blocks, such as MCU block 201, CAN transceivers 217, or power input block 212. High side drivers may be used to distribute power, rather than relays or fuse boxes, in some instances. It is contemplated herein that all or some blocks may be connected with MCU block 201.

The disclosed blocks may be further subdivided and may operate to execute on different functions that are supported by a particular ECU. For example, CAN transceivers block 217 (also CAN transceivers block 263 or CAN transceivers block 243) may have a plurality of CAN operations that may include platform CAN, body front CAN, or access CAN (e.g., access CAN may connect to the vehicles access modules).

The following are examples of circuit blocks or circuit block functions that may be associated with ECU 10, ECU 20, or ECU 30. Power input block 212 (also power input 260) may have functions associated with receiving power from one or more sources and distributing the received power, among other functions. Different power sources may be LV battery 60, DCDC 50 (e.g., high voltage DCDC), 12V DCDC (e.g., low voltage DCDC), or jumpstart source (e.g., external source connected with jumpstart access 17). Power input block 212 may include functions (e.g., logic) associated with BidDi switch 12, fault isolation system 11 (e.g., battery isolation switch), voltage power monitoring, or logic/analog power logic (e.g.,5V Vref (e.g., reference voltage) or 5V Vcc (positive supply rail)). Fault isolation system 11 may include receiving or sending indications associated with monitoring switch status of isolation system 11, MOSFET temperature, over voltage protection status, or reset of fault isolation system 11, among other things. Power input block 212 may include controls associated with distributing power to OR loads, such as common bus 15 and OR loads 14.

In an example, power supplies block 213 (also power supplies block 262) may include functions which may be connected with or separate from power input block 212. In an example, power supplies block 213 may be connected with power input block 212 and share LV battery ORing power. Power supplies block 213 may include different functions used in power supply enabling (e.g., ethernet power enabling) or disabling (e.g., pilot 5V disabling), In addition power supplies block 213 may include functions associated with power management integrated circuits (PMIC), such as waking, errors, eFuse, or the like.

With continued reference to power supplies block 213, there may be functionality used to power MCU 201, used to power transceivers, used to power analog circuits, used to power external devices, used to power the MCU 201 during sleep (e.g., standby mode), used to power digital devices on the board (which may be used as always ON power during sleep), used to power secure element (e.g., secure element 216), used to power ethernet (e.g., Ethernet physical block 218), or the like. The power used may be of different voltages, such as 3V, 5V, or 12V.

Power supplies block 213 may have functionality that may include a reference voltage for an analog-to-digital converter (ADC) of a MCU (e.g., MCU 201), a filter for filtering LV battery to power low current devices, functionality used to wake up PMIC from an external wake vector source, functionality used to wake up a ECU (e.g., ECU 10) from an external wake vector source, power on reset functionality used to reset MCU 201 upon power up, power on reset functionality used to reset MCU upon fault conditions, or an alternate voltage reference with a MCU 201 that may be redundant to a primary voltage reference. Power supplies block 213 may have multiple safe state pins. The safe state pins, for example, may be used to shut down devices and put them in fail safe state if MCU 201 is inoperable.

In an example, low voltage (e.g., 10V to 14V) DCDC support block 214 may include functions associated with low voltage DCDC switching or voltage monitor wakes. Voltage monitor wakes may include a battery temperature wake, overcharge wake, undervoltage wake, or the like. Low voltage (e.g., 12V) DCDC support block 214 may have functionality that may include an alternate voltage reference with a MCU 201 that may be redundant to a primary voltage reference.

In an example, I/O expanders block 215 (also I/O expanders block 275) may allow for the addition of extra I/O, which may be for eFuses connections, HSD connections, or other connections for blocks which may be disclosed herein.

In an example, switch monitor block 220 (also switch monitor block 266 or switch monitor block 248) may be used in vehicle 300 to connect multiple switches or sensors to a microcontroller (e.g., MCU 201). Switch monitor block 220 may enable the detection of multiple switch states or sensor outputs through a communication channel.

In an example, local interconnect network (LIN) transceivers block 219 (also LIN transceivers block 265 or LIN transceivers block 244) may include multiple communication LIN transceiver blocks. A LIN transceiver is an electronic component that enables communication between devices in a vehicle's network using the LIN (Local Interconnect Network) protocol. It acts as an interface between the microcontroller and the LIN bus, allowing data transmission and reception. LIN transceivers may be used in automotive systems body control modules (BCM), infotainment systems, sensor networks, or the like.

In an example, HSD block 225, HSD block 226, or HSD block 227 (also HSD block 277, HSD block 278, HSD block 279, HSD block 252, or HSD block 253) may be used in conjunction with LED lighting, motor control, or battery management of vehicle 300. High side drivers (HSDs) may assist with control the switching of a load connected between the driver and the positive voltage rail. HSDs may help the on-board microcontroller (e.g., MCU 201) to identify or isolate faults.

In an example, MCU 201 (also MCU 240 or MCU 261) may act as the central nervous system, processing data from vehicle sensors or executing control algorithms for one or more ECUs (e.g., ECU 10, ECU 20, or ECU 30), among other things. MCU 201 may manage various physical or logical components of vehicle 300, such as motors, battery, or power electronics. MCU 201 may manage functions via connections with corresponding circuit blocks, as disclosed herein. MCU 201 may be used to implement functionality which may include optimizing performance of the various components of vehicle 300 (e.g., optimize battery life or electric motor performance).

Other functions of ECU 30 blocks may include the following. Full-bridge driver block—integrated 229 or full-bridge driver block—pre drivers 230 (also full-bridge driver block 268 or full-bridge driver block 251) may be used to switch each side of a full-bridge or half-bridge circuit (e.g., half-bridge block 274) with a pulse wave modulation signal. A full-bridge driver may be used in power converters, motor control applications, or the like. Full bridge may be used to drive motors used for body controls. Those motors may be the following: window motors, seat positioning motors, latches, or frunk actuators.

Stepper motor driver block 231 (also stepper motor driver block 267) may be used for control of an electrical motor that rotates in a series of small angular steps, instead of continuously. Secure element block 216 may be used for cryptographic calculations and authentication for a user of the vehicle for unlocking the door or the like.

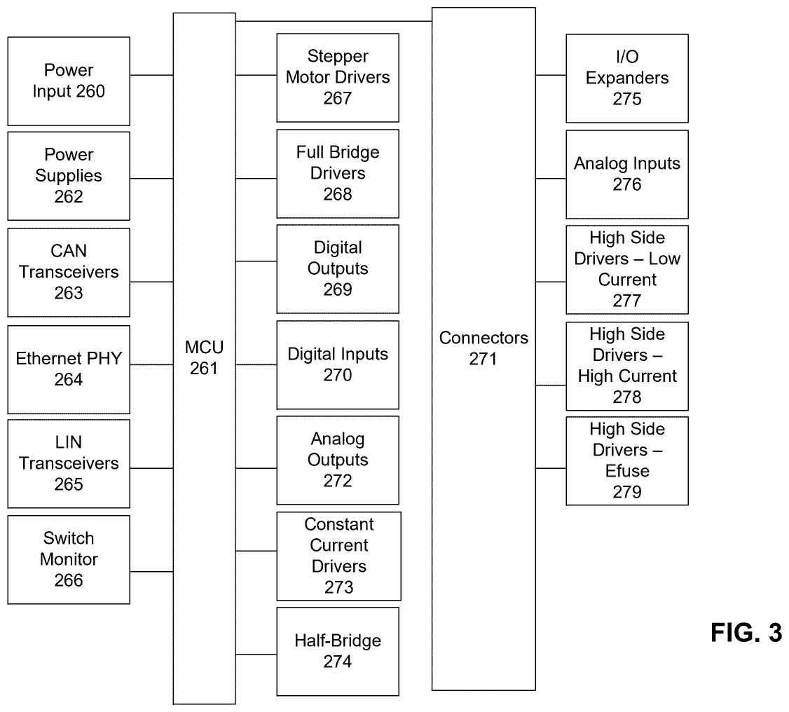

FIG. 3 illustrates an example schematic block diagram of the circuit blocks of ECU 20 of FIG. 1C. ECU 20 may be located on the west (e.g., left) side of vehicle 300. ECU 20 may include functions, such as control vehicle chassis and suspension, control left door functions, distribute power to front left of vehicle 300, control thermal system components, monitor inputs switches, control left side seats, control charge port door, or front left headlamps, among other things. These functions may be executed in part by one or more blocks as disclosed herein.

As shown, there may be several functions unique to ECU 20 and therefore unique circuit blocks to each ECU. In another example, ECU 20 may include constant current drivers block 273, or half-bridge block 274, among others that may not be present in other zones. ECU 20 may include connectors block 271, power input block 260, power supplies block 262, I/O expanders block 275, CAN transceivers block 263, Ethernet PHY block 264, LIN transceivers block 265, switch monitor block 266, digital inputs block 270, digital outputs block 269, analog inputs block 276, analog outputs block 272, high side drivers—low current block 277, high side drivers—high current block 278, high side drivers—eFuse block 279, full bridge drivers block 268, MCU block 261, or stepper motor drivers block 267. In an example, constant current drivers block 273 may be an electrical component that provides a stable and consistent amount of electrical current, usually for LED lighting. It is contemplated that the blocks may be communicatively connected with each other. It is contemplated herein that all or some blocks may be connected to MCU block 261.

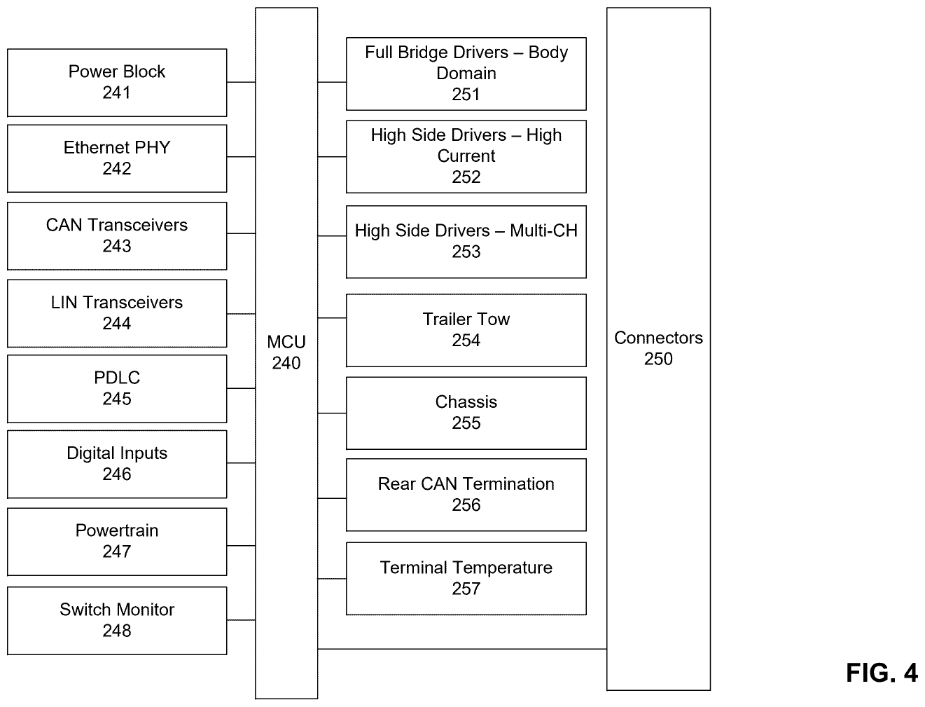

FIG. 4 illustrates an example schematic block diagram of the circuit blocks of ECU 30 of FIG. 1C. ECU 30 may be located on the south side (e.g., rear) of vehicle 300. ECU 30 may include functions, such as trailer tow, lift gate/tail gate control, rear external lighting, electrochromic roof tint, rear chassis control (dampers, ride height), rear lighting features (e.g., external lighting), trailer tow features, rear windshield features, active suspension features, rear propulsion features, rear power distribution, rear closure features, or auxiliary air features, among other things. These functions may be executed in part by one or more blocks as disclosed herein.

As shown, there may be several functions unique to ECU 30 and therefore unique circuit blocks to each ECU. In another example, ECU 30 may include PDLC 245, trailer tow block 254 (e.g., an electrical circuit to drive the motors or other operations for towing a trailer), powertrain block 247, rear CAN termination block 256, terminal temperature block 257, or chassis block 255, among others that may not be present in other zones. ECU 30 may include power block 241, Ethernet PHY block 242, CAN transceivers block 243, LIN transceivers (244), digital inputs block 246, full bridge drivers—body domain block 251, high side drivers—high current block 252, high side drivers—multi channel block 253, MCU 240, switch monitor block 248, or connectors block 250. It is contemplated that the blocks may be communicatively connected with each other. It is contemplated herein that all or some blocks may be connected to MCU block 240.

For ECU 30, power block 241 may have functions associated with receiving power from one or more sources and distributing the received power, among other functions. Different power sources may be LV battery 60, DCDC 50 (e.g., high voltage DCDC), LV DCDC, or 5V battery.

PDLC block 245 is the Polymer-Dispersed Liquid Crystal (PDLC) glass driver, which may be a DC to AC converter. Polymer-Dispersed Liquid Crystal (PDLC) glass is a type of smart glass that can switch between transparent and opaque states when an electrical voltage is applied. The “driver” in PDLC glass refers to the electronic control unit that manages the electrical voltage applied to the glass. The glass may be used on the roof of the vehicle. Powertrain block 247 may be used to control the system that generates power to move vehicle 300. Power sources that may be managed may include LV battery 60, LV DCDC 41, Vcc, or 5V_Vdd.

Other functions of ECU 30 blocks may include the following. HSD-multichannel block 253 may use HSD related functions with multiple channels. Trailer tow block 254 may include functions, such as trailer brake temperature, safety shutoffs, trailer door wake, or the like, associated with monitoring or control of trailer tow features. Chassis block 255 may include functions associated with monitoring or control of chassis features, such as dampers or ride height.

The methods, systems, or apparatuses disclosed herein may be incorporated into electric vehicles or other devices. The circuit blocks disclosed herein may be distributed with or combined with one or more ECUs or other devices. Some circuit block functionality may be repeated across multiple ECUs. Some circuit block functionality may be unique to an ECU (e.g., ECU 10 may be the only ECU with 12V DCDC block as described herein). The methods, systems, or apparatuses disclosed herein may be incorporated into products, such as various feature specific or zone specific electronic control units (ECUs).

As used herein, the phrase “at least one of” preceding a series of items, with the term “and” or “or” to separate any of the items, modifies the list as a whole, rather than each member of the list (i.e., each item). The phrase “at least one of” does not require selection of at least one of each item listed; rather, the phrase allows a meaning that includes at least one of any one of the items, and/or at least one of any combination of the items, and/or at least one of each of the items. By way of example, the phrases “at least one of A, B, and C” or “at least one of A, B, or C” each refer to only A, only B, or only C; any combination of A, B, and C; and/or at least one of each of A, B, and C.

When an element is referred to herein as being “connected” or “coupled” to another element, it is to be understood that the elements can be directly connected to the other element, or have intervening elements present between the elements. In contrast, when an element is referred to as being “directly connected” or “directly coupled” to another element, it should be understood that no intervening elements are present in the “direct” connection between the elements. However, the existence of a direct connection does not exclude other connections, in which intervening elements may be present.

The predicate words “configured to”, “operable to”, and “programmed to” do not imply any particular tangible or intangible modification of a subject, but, rather, are intended to be used interchangeably. In one or more implementations, a processor configured to monitor and control an operation or a component may also mean the processor being programmed to monitor and control the operation or the processor being operable to monitor and control the operation. Likewise, a processor configured to execute code can be construed as a processor programmed to execute code or operable to execute code.

Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases.

The word “exemplary” is used herein to mean “serving as an example, instance, or illustration”. Any embodiment described herein as “exemplary” or as an “example” is not necessarily to be construed as preferred or advantageous over other embodiments. Furthermore, to the extent that the term “include”, “have”, or the like is used in the description or the claims, such term is intended to be inclusive in a manner similar to the term “comprise” as “comprise” is interpreted when employed as a transitional word in a claim. In addition, the use of the word “or” is generally used inclusively unless otherwise provided herein.

All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for”.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein but are to be accorded the full scope consistent with the language claims, wherein reference to an element in the singular is not intended to mean “one and only one” unless specifically so stated, but rather “one or more”. Unless specifically stated otherwise, the term “some” refers to one or more. Pronouns in the masculine (e.g., his) include the feminine and neuter gender (e.g., her and its) and vice versa. Headings and subheadings, if any, are used for convenience only and do not limit the subject disclosure.

As disclosed herein an apparatus may include a low voltage battery (e.g., approximately 10V-14V) direct current to direct current converter circuit block, an electrochromic tint driver circuit block, or a secure element circuit block. The apparatus may include an electronic control unit of an electric vehicle. An apparatus may include a constant current drivers circuit block or a half-bridge circuit block. An apparatus may include a trailer tow circuit block or a powertrain circuit block. The components may be communicatively connected with each other. All combinations (including the removal or addition of components) in this paragraph and the above paragraphs are contemplated in a manner consistent with other portions of the detailed description.

Methods, systems, or apparatus with regard to zonal architecture for vehicle power distribution are disclosed herein. A vehicle may include an cast electronic control unit (ECU), a west ECU, and a south ECU. The east ECU may operate first components on a first side of a longitudinal axis of the vehicle, while the west ECU may operate second components on a second side of the longitudinal axis. The longitudinal axis may be defined as an imaginary line running from the front of the vehicle to the rear along its center, dividing the vehicle into the first and second sides. The south ECU may be positioned at the rear of the vehicle. The cast ECU may include a low voltage direct current to direct current (DCDC) support circuit block, which includes functions associated with low voltage DCDC switching or voltage monitor wakes. All combinations (including the removal or addition of components) in this paragraph and the above paragraphs are contemplated in a manner consistent with other portions of the detailed description.

The cast ECU may further include a power supplies circuit block connected with a power input circuit block, sharing low voltage battery ORing power. The power supplies circuit block may be used to power a microcontroller unit during standby mode and may have an alternate voltage reference redundant to a primary voltage reference. The east ECU may also include a secure element circuit block for cryptographic calculations and authentication associated with unlocking a vehicle door, a stepper motor driver circuit block to control an electrical motor rotating in angular steps, or an electrochromic tint driver circuit block to control mirror tint. All combinations (including the removal or addition of components) in this paragraph and the above paragraphs are contemplated in a manner consistent with other portions of the detailed description.

The west ECU may include a power supplies circuit block connected with a power input circuit block, sharing low voltage battery ORing power, or a stepper motor driver circuit block. It may also include a constant current drivers circuit block to provide consistent electrical current to components, such as light emitting diodes. The south ECU may include a polymer-dispersed liquid crystal (PDLC) circuit block for operating PDLC glass, a powertrain circuit block to control the system generating power for vehicle movement, a trailer tow circuit block for operating a trailer door wake component and controlling trailer tow features, or a chassis circuit block for operating dampers or ride height. The south ECU operates third components in the rear of the vehicle. All combinations (including the removal or addition of components) in this paragraph and the above paragraphs are contemplated in a manner consistent with other portions of the detailed description.

An alternative vehicle configuration may include an east ECU positioned on the first side of the longitudinal axis and a west ECU positioned on the second side, with an optional south ECU operating third components at the rear of the vehicle. In this configuration, the east ECU may also include a low voltage DCDC support circuit block with functions associated with low voltage DCDC switching. All combinations (including the removal or addition of components) in this paragraph and the above paragraphs are contemplated in a manner consistent with other portions of the detailed description.

What is claimed is:

1. A vehicle comprising:
an east electronic control unit (ECU), wherein the east ECU operates first components of a first side of a longitudinal axis of the vehicle, wherein the longitudinal axis is defined as an imaginary line running from a front of the vehicle to a rear of the vehicle along its center, dividing the vehicle into the first side and a second side;
a west ECU, wherein the west ECU operates second components of the second side of the longitudinal axis of the vehicle; and
a south ECU positioned at the rear of the vehicle.

2. The vehicle of claim 1, wherein the east ECU comprises a low voltage direct current to direct current (DCDC) support circuit block, wherein the DCDC support circuit block comprises one or more functions associated with low voltage DCDC switching or voltage monitor wakes.

3. The vehicle of claim 1, wherein the east ECU comprises a power supplies circuit block that is connected with power input circuit block, wherein the power supplies circuit block and power input circuit block share low voltage battery ORing power.

4. The vehicle of claim 1, wherein the east ECU comprises a power supplies circuit block that is used to power a microcontroller unit during a standby mode.

5. The vehicle of claim 1, wherein the east ECU comprises a power supplies circuit block that has an alternate voltage reference with a microcontroller unit that is redundant to a primary voltage reference.

6. The vehicle of claim 1, wherein the east ECU comprises a secure element circuit block that performs cryptographic calculations and authentication associated with unlocking a door of the vehicle.

7. The vehicle of claim 1, wherein the east ECU comprises a stepper motor driver circuit block that is used to control an electrical motor that rotates in a series of angular steps.

8. The vehicle of claim 1, wherein the east ECU comprises an electrochromic tint driver circuit block that is configured to control tint on mirrors.

9. The vehicle of claim 1, wherein the west ECU comprises a power supplies circuit block that is connected with power input circuit block, wherein the power supplies circuit block and power input circuit block share low voltage battery ORing power.

10. The vehicle of claim 1, wherein the west ECU comprises a stepper motor driver circuit block that is used to control an electrical motor that rotates in a series of angular steps.

11. The vehicle of claim 1, wherein the west ECU comprises constant current drivers circuit block that is configured to provide a consistent amount of electrical current to one or more components of the second components, wherein the one or more components of the second components comprises light emitting diodes.

12. The vehicle of claim 1, wherein the south ECU comprises a polymer-dispersed liquid crystal (PDLC) circuit block that is configured to operate PDLC glass to switch from opaque to transparent.

13. The vehicle of claim 1, wherein the south ECU comprises a powertrain circuit block that is configured to control a system that generates power to move the vehicle.

14. The vehicle of claim 1, wherein the south ECU comprises a trailer tow circuit block that is configured to operate a trailer door wake component.

15. The vehicle of claim 1, wherein the south ECU comprises a trailer tow circuit block that is configured to control one or more features of a trailer tow.

16. The vehicle of claim 1, wherein the south ECU comprises a chassis circuit block is configured to operate dampers or ride height.

17. The vehicle of claim 1, wherein the south ECU operates third components in the rear of the vehicle.

18. A vehicle comprising:
an east electronic control unit (ECU), wherein the east ECU is positioned on a first side of a longitudinal axis of the vehicle, wherein the longitudinal axis is defined as an imaginary line running from a front of the vehicle to a rear of the vehicle along its center, dividing the vehicle into the first side and a second side; and
a west ECU, wherein the west ECU positioned on the second side of the longitudinal axis of the vehicle.

19. The vehicle of claim 18, further comprise a south ECU that operates third components at the rear of the vehicle.

20. The vehicle of claim 18, wherein the east ECU comprises a low voltage direct current to direct current (DCDC) support circuit block, wherein the DCDC support circuit block comprises one or more functions associated with low voltage DCDC switching.
